(19) United States
(12) Patent Application Publication
(10) Pub. No.: US 2014/0217471 A1
(43) Pub. Date: Aug. 7, 2014

(54) Ga2O3 SEMICONDUCTOR ELEMENT

(71) Applicants: Kohei Sasaki, Tokyo (JP); Masataka Higashiwaki, Tokyo (JP); Shizuo Fujita, Kyoto-shi (JP)

(72) Inventors: Kohei Sasaki, Tokyo (JP); Masataka Higashiwaki, Tokyo (JP); Shizuo Fujita, Kyoto-shi (JP)

(73) Assignees: National Institute of Information and Communicatio ns Technology, Tokyo (JP); Tamura Corporation, Tokyo (JP)

(21) Appl. No.: 14/343,660

(22) PCT Filed: Sep. 7, 2012
(86) PCT No.: PCT/JP2012/072900

§ 371 Date: Mar. 7, 2014

(30) Foreign Application Priority Data
Sep. 8, 2011 (JP) 2011-196439

(51) Int. Cl. H01L 29/78

(52) U.S. Cl. CPC H01L 29/78
USPC 257/192

(57) ABSTRACT

Provided is a high-quality Ga₂O₃ semiconductor element. Provided is, as one embodiment of the present invention, a Ga₂O₃ MESFET (10), which includes: an n-type α-(AlₓGa₁₋ₓ)₂O₃ single crystal film (3), which is formed on an α-Al₂O₃ substrate (2) directly or with other layer therebetween, and is composed of an α-(AlₓGa₁₋ₓ)₂O₃ single crystal (0≦x≦1); a source electrode (12) and a drain electrode (13), which are formed on the n-type α-(AlₓGa₁₋ₓ)₂O₃ single crystal film (3); and a gate electrode (11), which is formed on a region between the source electrode (12) and the drain electrode (13) on the n-type α-(AlₓGa₁₋ₓ)₂O₃ single crystal film (3).

### TECHNICAL FIELD

The invention relates to a Ga₂O₃-based semiconductor element.

### BACKGROUND ART

A β-Ga₂O₃-based semiconductor element using a β-Ga₂O₃ crystal film formed on an α-Al₂O₃ (sapphire) substrate is known (see, e.g., NPL 1).

### CITATION LIST

### Non Patent Literature

[NPL 1]

K. Matsuzaki et al. Appl. Phys. Lett. 88, 092106, 2006.

### SUMMARY OF INVENTION

[Technical Problem]

However, it is difficult to grow a monoclinic β-Ga₂O₃ crystal film on an α-Al₂O₃ substrate having a corundum structure and it is not possible to obtain a high-quality β-Ga₂O₃ crystal film. Thus, it is difficult to form a high-quality Ga₂O₃-based semiconductor element by using a β-Ga₂O₃ crystal film grown on an α-Al₂O₃ substrate.

It is an object of the invention to provide a high-quality Ga₂O₃-based semiconductor element.

[Solution to Problem]

According to one embodiment of the invention, a Ga₂O₃-based semiconductor element as defined [1] to [3] below is provided so as to the above object.

[1] A Ga₂O₃-based semiconductor element, comprising:
an α-(AlₓGa₁₋ₓ)₂O₃ single crystal film that comprises an α-(AlₓGa₁₋ₓ)₂O₃ single crystal (0≦x≦1) and is formed on an α-Al₂O₃ substrate directly or via an other layer;
a source electrode and a drain electrode that are formed on the α-(AlₓGa₁₋ₓ)₂O₃ single crystal film; and
a gate electrode that is formed on a region between the source electrode and the drain electrode of the α-(AlₓGa₁₋ₓ)₂O₃ single crystal film

[2] The Ga₂O₃-based semiconductor element according to [1], further comprising a first contact region and a second contact region that comprise a same conductive type as the α-(AlₓGa₁₋ₓ)₂O₃ single crystal film, are formed in the α-(AlₓGa₁₋ₓ)₂O₃ single crystal film and are connected to the source electrode and the drain electrode, respectively.

[3] The Ga₂O₃-based semiconductor element according to [2], wherein the α-(AlₓGa₁₋ₓ)₂O₃ single crystal film, the first contact region and the second contact region are of an n-type.

[Advantageous Effects of Invention]

According to an embodiment of the invention, a high-quality Ga₂O₃-based semiconductor element can be provided.

### BRIEF DESCRIPTION OF DRAWINGS

[FIG. 1]

FIG. 1 is a cross sectional view showing a Ga₂O₃-based MESFET in an embodiment.

[FIG. 2]

FIG. 2 is a structural diagram illustrating an example of an MBE system used for forming an α-(AlₓGa₁₋ₓ)₂O₃ single crystal film.

### DESCRIPTION OF EMBODIMENTS

According to the present embodiment, it is possible to form a high-quality α-(AlₓGa₁₋ₓ)₂O₃ single crystal film on an α-Al₂O₃ substrate by homoepitaxial growth and use of such a high-quality α-(AlₓGa₁₋ₓ)₂O₃ single crystal film allows a high-quality Ga₂O₃-based semiconductor element to be formed. Examples of embodiments thereof will be described in detail below.

### Embodiment

A Ga₂O₃-based MESFET (Metal Semiconductor Field Effect Transistor) will be described as the Ga₂O₃-based semiconductor element in the embodiment.

(Structure of Ga₂O₃-based semiconductor Element)

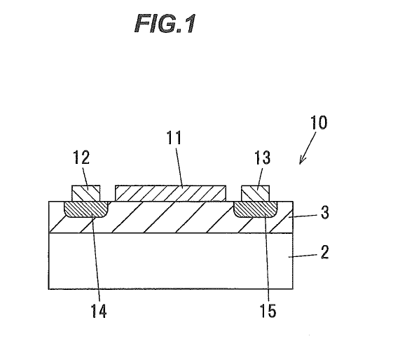

FIG. 1 is a cross sectional view showing a Ga₂O₃-based MESFET in the embodiment. A Ga₂O₃-based MESFET 10 includes an n-type α-(AlₓGa₁₋ₓ)₂O₃ single crystal film 3 formed on an α-Al₂O₃ substrate 2, a source electrode 12 and a drain electrode 13 which are formed on the n-type α-(AlₓGa₁₋ₓ)₂O₃ single crystal film 3, contact regions 14 and 15 which are formed in the n-type α-(AlₓGa₁₋ₓ)₂O₃ single crystal film 3 respectively under the source electrode 12 and the drain electrode 13, and a gate electrode 11 which is formed on the n-type α-(AlₓGa₁₋ₓ)₂O₃ single crystal film 3 in the region between the source electrode 12 and the drain electrode 13.

The source electrode 12 is electrically connected to the drain electrode 13 via the n-type β-Ga₂O₃ single crystal film 3. Meanwhile, a Schottky junction is formed at an interface between the gate electrode 11 and the n-type β-Ga₂O₃ single crystal film 3 and a depletion layer is thus formed in the n-type β-Ga₂O₃ single crystal film 3 under the gate electrode 11. The Ga₂O₃-based MESFET 10 functions as either a normally-off transistor or a normally-on transistor depending on the thickness of the depletion region.

The n-type α-(AlₓGa₁₋ₓ)₂O₃ single crystal film 3 is an α-(AlₓGa₁₋ₓ)₂O₃ (0≦x≦1) single crystal film formed on the α-Al₂O₃ substrate 2. The n-type α-(AlₓGa₁₋ₓ)₂O₃ single crystal film 3 includes an n-type dopant such as Sn, Ti, Zr, Hf, V, Nb, Ta, Mo, W, Ru, Rh, Ir, C, Si, Ge, Pb, Mn, As, Sb, Bi, F, Cl, Br and I. The n-type α-(AlₓGa₁₋ₓ)₂O₃ single crystal film 3 includes an n-type dopant at a concentration of, e.g, not less than 1×10¹⁵/cm³ and not more than 1×10¹⁹ cm³. In addition, the thickness of the n-type α-(AlₓGa₁₋ₓ)₂O₃ single crystal film 3 is, e.g., 0.1 to 10 μm.

Here, another film such as an undoped β-Ga₂O₃ single crystal film may be formed between the α-Al₂O₃ substrate 2 and the n-type α-(AlₓGa₁₋ₓ)₂O₃ single crystal film 3. In this case, the undoped β-Ga₂O₃ single crystal film is formed on the α-Al₂O₃ substrate 2 by epitaxial growth and the n-type (AlₓGa₁₋ₓ)₂O₃ single crystal film 3 is formed on the undoped β-Ga₂O₃ single crystal film by epitaxial growth.

The gate electrode 11, the source electrode 12 and the drain electrode 13 are formed of, e.g., a metal such as Au, Al, Ti, Sn, Ge, In, Ni, Co, Pt, W, Mo, Cr, Cu and Pb, an alloy containing two or more of such metals, a conductive compound such as ITO, or a conductive polymer. Polythiophene derivatives (PEDOT: poly(3,4-ethylenedioxythiophene)) doped with polystyrene sulfonate (PSS) or polypyrrole derivatives doped with TCNA are used as the conductive polymer. In addition, the structure thereof may be a two-layer structure composed of two different metals, e.g., Al/Ti, Au/Ni or Au/Co.

The contact regions 14 and 15 are regions having a high n-type dopant concentration formed in the n-type α-(AlₓGa₁₋ₓ)₂O₃ single crystal film 3 and are respectively connected to the source electrode 12 and the drain electrode 13. The n-type dopant included in the contact regions 14 and 15 and that included in the n-type α-(AlₓGa₁₋ₓ)₂O₃ single crystal film 3 may be either the same or different. The contact regions 14 and 15 include the n-type dopant at a concentration of, e.g., not less than 1×10¹⁸/cm³ and not more than 5×10¹⁹ cm³. It should be noted that the contact regions 14 and 15 do not need to be provided in the Ga₂O₃-based MESFET 10.

(Method of Manufacturing Ga₂O₃-based MESFET)

A process using the Molecular Beam Epitaxy (MBE) will be described below as an example of the method of manufacturing the α-(AlₓGa₁₋ₓ)₂O₃ single crystal film. The MBE is a crystal growth method in which a single or compound solid is heated in an evaporation source called cell and vapor generated by heat is supplied as a molecular beam onto the surface of the substrate.

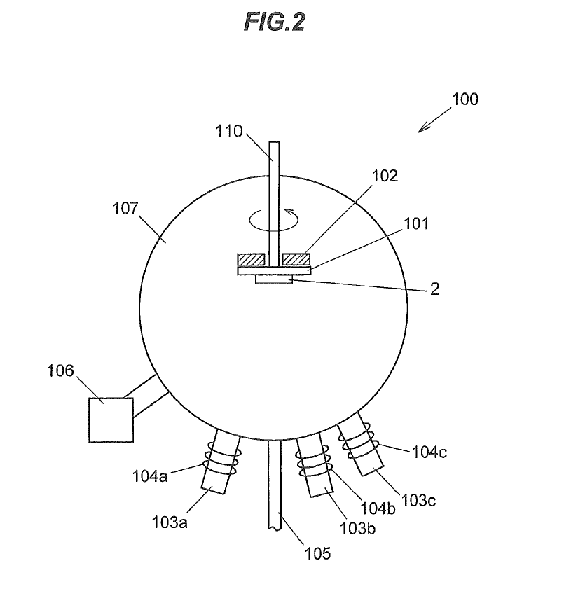

FIG. 2 is a structural diagram illustrating an example of an MBE system used for forming the α-(AlₓGa₁₋ₓ)₂O₃ single crystal film. The MBE system 100 is provided with a vacuum chamber 107, a substrate holder 101 supported in the vacuum chamber 107 to hold the α-Al₂O₃ substrate 2, heating devices 102 held on the substrate holder 101 to heat the α-Al₂O₃ substrate 2, plural cells 103 (103a, 103b, 103c) each provided for each atom or molecule constituting a thin film, heaters 104 (104a, 104b, 104c) for hearing the plural cells 103, a gas supply pipe 105 for supplying oxygen-based gas into the vacuum chamber 107, and a vacuum pump 106 for exhausting the air in the vacuum chamber 107. It is configured that the substrate holder 101 can be rotated by a non-illustrated motor via a shaft 110.

A Ga raw material of the α-(AlₓGa₁₋ₓ)₂O₃ single crystal film, such as Ga powder, is loaded in the first cell 103a. The Ga powder desirably has a purity of not less than 6N. Powder of an n-type dopant raw material to be doped as a donor is loaded in the second cell 103b. An Al raw material of the α-(AlₓGa₁₋ₓ)₂O₃ single crystal film, such as Al powder, is loaded in the third cell 103c. A shutter is provided at an opening of each of the first cell 103a, the second cell 103b and the third cell 103c.

Firstly, the α-Al₂O₃ substrate 2 is attached to the substrate holder 101 of the MBE system 100. Next, the vacuum pump 106 is activated to reduce atmospheric pressure in the vacuum chamber 107 to about 10¹⁸ Torr. Then, the α-Al₂O₃ substrate 2 is heated by the heating devices 102. Here, radiation heat of heat source such as graphite heater of the heating device 102 is thermally transferred to the α-Al₂O₃ substrate 2 via the substrate holder 101 and the α-Al₂O₃ substrate 2 is thereby heated.

After the α-Al₂O₃ substrate 2 is heated to a predetermined temperature, oxygen-based gas is supplied into the vacuum chamber 107 through the gas supply pipe 105.

After a period of time required for stabilization of gas pressure in the vacuum chamber 107 (e.g., after 5 minutes) since the oxygen-based gas was supplied into the vacuum chamber 107, the first cell 103a, the second cell 103b and the second cell 103c are respectively heated by the first heater 104a, the second heater 104b and the third heater 104c while rotating the substrate holder 101 so that Ga, Al and n-type dopant are evaporated and are radiated as molecular beam onto the surface of the α-Al₂O₃ substrate 2.

As such, the α-(AlₓGa₁₋ₓ)₂O₃ single crystal is epitaxially grown on the main surface of the α-Al₂O₃ substrate 2 while being doped with the n-type dopant such as Sn and the n-type α-(AlₓGa₁₋ₓ)₂O₃ single crystal film 3 is thereby formed. It should be noted that as the n-type dopant other than Sn, it is possible to use Ti, Zr, Hf, V, Nb, Ta, Mo, W, Ru, Rh, Ir, C, Si, Ge, Pb, Mn, As, Sb and Bi, etc., for substituting Ga or Al site and it is possible to use F, Cl, Br and I, etc., for substituting oxygen site. The addition concentration of the n-type dopant can be controlled by temperature of the second cell 103b.

Alternatively, the n-type α-(AlₓGa₁₋ₓ)₂O₃ single crystal film 3 may be formed by the PLD (Pulsed Laser Deposition) or the CVD (Chemical Vapor Deposition) etc.

Next, the contact regions 14 and 15 are formed by ion-planting the n-type dopant such as Sn into the n-type α-(AlₓGa₁₋ₓ)₂O₃ single crystal film 3. It should be noted that the ion to be implanted is not limited to Sn and, when substituting, e.g., Ga or Al site, it is possible to use Ti, Zr, Hf, V, Nb, Ta, Mo, W, Ru, Rh, Ir, C, Si, Ge, Pb, Mn, As, Sb or Bi. In addition, it is possible to use F, Cl, Br or I when substituting oxygen site.

The implantation concentration is, e.g., not less than 1×10¹⁸/cm³ and not more than 5×10¹⁹ cm³. The implantation depth is not less than 30 nm. After implantation, the surface of the implanted region is etched about 10 nm by hydrofluoric acid. Sulfuric acid, nitric acid or hydrochloric acid may be used for the etching. After that, implantation damage is repaired by performing annealing treatment in a nitrogen atmosphere at not less than 800° C. for not less than 30 minutes. In case of performing the annealing treatment in an oxygen atmosphere, treatment temperature is not less than 800° C. and not more than 950° C. and treatment time is not less than 30 minutes.

It should be noted that the method of forming the contact regions 14 and 15 is not limited to ion implantation and thermal diffusion process may be used. In this case, after metal such as Sn is brought into contact with the n-type α-(AlₓGa₁₋ₓ)₂O₃ single crystal film 3 in a region for the contact regions 14 and 15 to be formed, heat treatment is performed to diffuse a dopant such as Sn into the n-type α-(AlₓGa₁₋ₓ)₂O₃ single crystal film 3.

After that, the gate electrode 11, the source electrode 12 and the drain electrode 13 are formed.

(Effects of the Embodiment)

According to the present embodiment, it is possible to form high-quality α-(AlₓGa₁₋ₓ)₂O₃ single crystal films by homoepitaxial growth and use of such α-(AlₓGa₁₋ₓ)₂O₃ single crystal films allows high-quality Ga₂O₃-based semiconductor elements to be formed. In addition, these Ga₂O₃-based semiconductor elements have excellent performance since a high-quality α-(AlₓGa₁₋ₓ)₂O₃ single crystal film is used as a channel layer.

It should be noted that the invention is not intended to be limited to the above-mentioned embodiment, and the various kinds of modifications can be implemented without departing from the gist of the invention. For example, the Ga₂O₃-based semiconductor element has been described as the n-type semiconductor element in the embodiment but may be a p-type semiconductor element. In this case, the conductivity type (n-type or p-type) of each member is all inverted.

Although the embodiment of the invention has been described above, the invention according to claims is not to be limited to the above-mentioned embodiment. Further, it should be noted that all combinations of the features described in the embodiment are not necessary to solve the problem of the invention.

### INDUSTRIAL APPLICABILITY

A high-quality Ga₂O₃-based semiconductor element is provided.

### REFERENCE SIGNS LIST

2: α-Al₂O₃ substrate

3: n-type α-(AlₓGa₁₋ₓ)₂O₃ single crystal film

10: Ga₂O₃-based MESFET

11: gate electrode

12: source electrode

13: drain electrode

14, 15: contact region

1. A Ga₂O₃-based semiconductor element, comprising:
an α-(AlₓGa₁₋ₓ)₂O₃ single crystal film that comprises an α-(AlₓGa₁₋ₓ)₂O₃ single crystal (0≦x≦1) and is formed on an α-Al₂O₃ substrate directly or via an other layer;
a source electrode and a drain electrode that are formed on the α-(AlₓGa₁₋ₓ)₂O₃ single crystal film; and
a gate electrode that is formed on a region between the source electrode and the drain electrode of the α-(AlₓGa₁₋ₓ)₂O₃ single crystal film.

2. The Ga₂O₃-based semiconductor element according to claim 1, further comprising a first contact region and a second contact region that comprise a same conductive type as the α-(AlₓGa₁₋ₓ)₂O₃ single crystal film, are formed in the α-(AlₓGa₁₋ₓ)₂O₃ single crystal film and are connected to the source electrode and the drain electrode, respectively.

3. The Ga₂O₃-based semiconductor element according to claim 2, wherein the α-(AlₓGa₁₋ₓ)₂O₃ single crystal film, the first contact region and the second contact region are of an n-type.
